(19) United States
(12) Patent Application Publication
(10) Pub. No.: US 2006/0033039 A1
(43) Pub. Date: Feb. 16, 2006

(54) Photo-controlled luminescence sensor system

(76) Inventors: John R. Williams, Lexington, MA (US); Henry Raczkowski, Salem, MA (US); Paul Lane, Arlington, VA (US); Andrew Meulenberg, Bedford, MA (US)

Correspondence Address: Iandiorio & Teska, 260 Bear Hill Road, Waltham, MA, 02451-1018, US

(21) Appl. No.: 10/916,701

(22) Filed: Aug. 12, 2004

(51) Int. Cl. H01L 31/00; G01N 29/036

(52) U.S. Cl. 250/483.1; 257/431; 257/439; 73/653; 73/579

(57) ABSTRACT

A photo-controlled luminescence sensor system comprising a photo-controlled acoustic wave device, an oscillator device for driving said photo-controlled acoustic wave device at a predetermined frequency, said photo-controlled acoustic wave device including a photo-conductor medium which changes its electrical conductivity in response to incident radiation (light) to vary the predetermined frequency of said photo-controlled acoustic wave device, and a frequency detection device for determining a change in said predetermined frequency caused by the radiation induced change in the conductivity of the photo-conductor medium.

### FIELD OF THE INVENTION

This invention relates to a highly sensitive photo-controlled luminescence sensor system for detecting mass and luminescence of a sample.

### BACKGROUND OF THE INVENTION

Conventional mass sensor systems are used to measure the mass of a substance. Conventional light or luminescence sensor systems are used to detect the presence and/or concentration of a luminescing sample. Hence, utilizing conventional mass and luminescence sensor systems to determine both the mass and the presence and/or concentration of a luminescing sample requires both a mass and a luminescence sensor. Moreover, as the sample size and quantity become smaller, the mass and luminescence systems become more complicated and expensive.

Conventional luminescence sensor systems typically rely on measuring a change in the electrical output of a photosensitive circuit element to determine a shift in amplitude of a resonant frequency that is characteristic of the luminescent material. Such design is typically limited by error and noise when the sample size is reduced and/or concentration is low. Thus, conventional luminescence sensor systems typically employ complicated electronics and/or optics to stabilize the measured resonant frequencies and amplitudes. As a result, conventional luminescence detection systems have limited sensitivity to luminescing samples. Conventional luminescence and mass sensor systems also require several minutes to determine the dry mass of a sample and to detect and/or determine the concentration of luminescing samples because conventional systems must wait until the sensor achieves a predetermined sample temperature (e.g., after a sample solution has evaporated). Temperature changes in the sensors of conventional luminescence systems also generate noise and resonant frequency shifts which leads to decreased sensitivity and inaccurate measurements.

Prior art luminescence sensor systems also rely on measuring the flow of photocarriers generated by light (typically low level light) produced from photoexcitation of the active luminescent material. The photocarriers are typically generated within a biased semiconductor device which produces a photocurrent that is amplified to a level that can be more accurately measured. These measurements are limited by the sensitivity of the photo-detector, the stability and noise of the excitation light source(s), the photon-collecting optics, the photo-detector, the amplifier, and the conditioning and processing electronics.

### SUMMARY OF THE INVENTION

It is a further object of this invention to provide such a photo-controlled luminescence sensor system which more accurately measures the luminescence of a sample.

It is a further object of this invention to provide such a photo-controlled luminescence sensor system which measures both the mass and luminescence of a sample.

It is a further object of this invention to provide such a photo-controlled luminescence-sensor system which detects the presence of luminescing samples by measuring a light induced resonant frequency shift in a photo controlled acoustic wave device of the system.

It is a further object of this invention to provide such a photo-controlled luminescence sensor system which accurately and efficiently detects luminescing samples.

It is a further object of this invention to provide such a photo-controlled luminescence sensor system which utilizes light to enhance the resonant frequency stability of the system.

It is a further object of this invention to provide such a photo-controlled luminescence sensor system which utilizes light to tune and control the resonant frequency of the system.

It is a further object of this invention to provide such a photo-controlled luminescence sensor system which rapidly tracks any changes in the presence and/or activity of luminescence in samples.

It is a further object of this invention to provide such a photo-controlled luminescence sensor system which rapidly determines the concentration of luminescing samples.

It is a further object of this invention to provide such a photo-controlled luminescence sensor system which uses light to compensate for thermally induced resonant frequency shifts.

The invention results from the realization that a truly innovative photo-controlled luminescence system which measures both the mass and luminescence of a sample can be achieved with a photo-controlled acoustic wave device, an oscillator which drives a photo-controlled acoustic wave device at a predetermined frequency, the photo-controlled acoustic wave device includes a photo-conductor medium which changes its electrical conductivity in response to incident radiation to vary the predetermined frequency of the photo-controlled acoustic wave device, and a frequency detection device which determines a change in the predetermined frequency caused by the radiation induced change in the conductivity of the photo-conductor medium.

This invention features a photo-controlled luminescence sensor system including a photo-controlled acoustic wave device, an oscillator device for driving the photo-controlled acoustic wave device at a predetermined frequency, the photo-controlled acoustic wave device including a photo-conductor medium which changes its electrical conductivity in response to incident radiation to vary the predetermined frequency of the photo-controlled acoustic wave device, and a frequency detection device for determining a change in the predetermined frequency caused by the radiation induced change in the conductivity of the photo-conductor medium.

In a preferred embodiment, the photo-controlled acoustic wave device may include a flexural plate wave device. The photo-controlled acoustic wave device may include a surface acoustic wave device. The predetermined frequency may be the resonant frequency of the photo-controlled acoustic wave device. The predetermined frequency may be a change in frequency at a predetermined phase. The predetermined frequency may be in the range of about 100 KHz to 10 GHz. The predetermined frequency may be in the range of about 10 MHz to 100 MHz. The predetermined frequency may be in the range of about 1 MHz to 100 MHz. The photo-conductor medium may be chosen from the groups consisting of semiconductor and selected non-conductor mediums. The non-conductor medium may be chosen from the group consisting of indium-tin-oxide, organic dyes, metal salts, and lead sulfide. The semiconductor medium may be chosen from the group consisting of silicon, germanium, gallium arsenide, and indium arsenide. The photo-conductor medium may be crystalline or non-crystalline. The semiconductor medium may be undoped. The semiconductor medium may be lightly doped with a doping element to change the dark conductivity of the photo conductor medium while maintaining the photo-conductivity of the photo-conductor medium. The doping element may be chosen from the group consisting of boron, aluminum, arsenic, and phosphorus. The semiconductor medium may be doped at a concentration of approximately 10¹⁵ cm⁻³. The doped medium may be doped at a concentration of less than 10¹⁵ cm⁻³. The semiconductor medium may be doped at a concentration range of approximately 10¹³ cm⁻³ to 10¹⁵ cm⁻³. The change in electrical conductivity may be in the range of about 10 to 10⁻⁶/Ωm. The photo-controlled acoustic wave device may include a piezoelectric layer. The photo-controlled luminescence sensor system may further include a first set of transducers disposed on the piezoelectric layer and a second set of transducers disposed on the piezoelectric layer, spaced from the first set of transducers. The first set of transducers may define a drive comb and the second set of transducers may define a sense comb. The photo-controlled luminescence sensor system may further include a light source for emitting the incident radiation. The photo-controlled luminescence sensor system may include a temperature sensor for measuring the temperature of the photo-controlled acoustic wave device and the photo-conductor medium, and an optical controller device for controlling the amount of light emitted by the light source and compensating for resonant frequency shifts that result from temperature changes in the photo-conductive medium and the photo-controlled acoustic wave device.

This invention also features a photo-controlled luminescence sensor system including a flexural plate wave device, an oscillator device for driving the flexural plate wave device at a predetermined frequency, the flexural plate wave device including a photo-conductor medium which changes its electrical conductivity in response to sensed luminescing samples to vary the predetermined frequency of the flexural plate wave device, and a frequency detection device for determining a change in the predetermined frequency caused by the luminescence induced change in the conductivity of the photo-conductor medium representative of the presence and/or concentration of the luminescing samples.

In a preferred embodiment, the photo-controlled luminescence sensor system may include a light source that emits light for exciting the luminescing samples to increase the luminescence light emitted by the luminescing sample. The light source may direct light essentially parallel to the flexural plate wave device. The light source may direct light at an incident angle to the flexural plate wave device for illuminating the samples in a solution disposed in a well of the flexural plate while the light does not illuminate the photo-conductive layer. The photo-controlled luminescence sensor may include a light filter for selectively blocking excitation light from the photo-conductor medium. The light filter and the incident angle of light may be selected to optimize the ratio of the luminescence light to excitation light which is collected by the photo-conductive layer. A filter transmission ratio of the luminescence light to excitation light may be about 100. The system may include a light confinement device for confining the excitation light by total internal reflection to prevent excitation light from entering the photo-conductive medium. The light confinement device may include a light pipe. The light confinement device may include one or more low refractive index layers. The luminescing samples may be attached to low refractive-index layer. The luminescing samples may include antibodies and antigens. The flexural plate wave device may include a plurality of spaced walls which define a well for receiving a fluid sample. The photo-controlled luminescence sensor system may include a switching device for switching between mass and luminescence detection. A frequency difference between the excitation light source being turned on and off may provide a quantitative measure of the luminescence.

This invention also features a photo-controlled luminescence sensor system including a photo-controlled acoustic wave device, an oscillator device for driving the photo-controlled acoustic wave device at a predetermined frequency, the photo-controlled acoustic wave device including a photo-conductor medium which changes its electrical conductivity in response to sensed luminescing samples to vary the predetermined frequency of the flexural plate wave device, a frequency detection device for determining a change in the predetermined frequency caused by the luminescence induced change in the conductivity of the photo-conductor medium representative of the presence of the luminescing samples and a light source for exciting the luminescing samples to increase the luminescing of the sample, and a switching device for switching between mass and luminescence detection.

This invention further features a photo-controlled luminescence sensor system including a light source for emitting light, a photo-controlled acoustic wave device, an oscillator device for driving the photo-controlled acoustic wave device at a predetermined frequency, the photo-controlled acoustic wave device including a photo-conductor medium which changes its electrical conductivity in response to the light to vary the predetermined frequency of the photo-controlled acoustic wave device, a frequency detection device for determining a change in the predetermined frequency caused by the radiation induced change in the conductivity of the photo-conductor medium, a temperature sensor for monitoring the temperature of the photo-controlled acoustic device and the photo-conductive layer, and an optical controller device for controlling the amount of light emitted by the light source and compensating for resonant frequency shifts that result from temperature changes in the photo-conductive medium and the photo-controlled acoustic wave device.

### BRIEF DESCRIPTION OF THE DRAWINGS

Other objects, features and advantages will occur to those skilled in the art from the following description of a preferred embodiment and the accompanying drawings, in which:

FIG. 1 is a schematic block diagram showing the primary components of one embodiment of the photo-controlled luminescence sensor system of this invention;

FIG. 2 is a graph showing various exposures of light and the corresponding resonant frequency shift of the photo-controlled luminescence sensor system shown in FIG. 1;

FIG. 3 is a graph showing the relationship between the resonant frequency shift and light intensity of the photo-controlled luminescence sensor system shown in FIG. 1;

FIG. 4 is a schematic side view of another embodiment of the photo-controlled sensor system of this invention employing optical feedback to control the resonant frequency, resulting from temperature variation in the photo-conductive medium and photo-acoustic wave device of this invention;

FIG. 5 is a schematic top view showing the various electronic components and example drive and sense combs of the photo-controlled sensor system shown in FIGS. 1 and 4;

FIG. 6 is a schematic side view of an example of a flexure plate wave device employed in the photo-controlled sensor system of this invention;

FIG. 7 is a schematic side view of yet another embodiment of the photo-controlled luminescence sensor system of this invention employing a light confinement device and an optical entrance having alternating refractive index layers to control the incident radiation on the photo-conductor medium;

FIGS. 8A and 8B are schematic side views of the photo-controlled luminescence sensor system of this invention employing various optical filters; and

FIG. 9 is a schematic side view of another embodiment of this invention employing a light pipe.

### DISCLOSURE OF THE PREFERRED EMBODIMENT

Aside from the preferred embodiment or embodiments disclosed below, this invention is capable of other embodiments and of being practiced or being carried out in various ways. Thus, it is to be understood that the invention is not limited in its application to the details of operation, construction and arrangements of components set forth in the following description or illustrated in the drawings. If only one embodiment is described herein, the claims hereof are not to be limited to that embodiment. Moreover, the claims hereof are not to be read restrictively unless there is clear and convincing evidence manifesting a certain exclusion, restriction, or disclaimer.

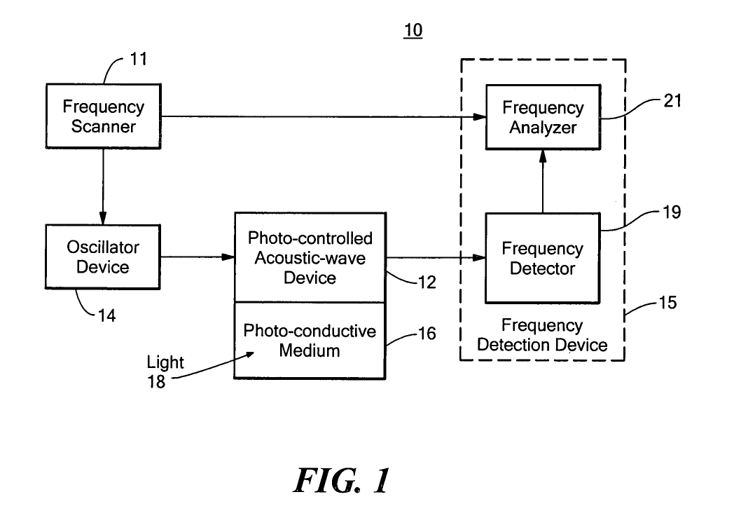

There is shown in FIG. 1, photo-controlled luminescence sensor system 10 of this invention. System 10 includes photo-controlled acoustic wave device 12, e.g., a flexural plate wave device or a surface acoustic wave device as known to those skilled in the art. Oscillator device 14 drives photo-controlled acoustic wave device 12 at a predetermined frequency. Ideally, the predetermined frequency is the resonant frequency of photo-controlled acoustic wave device 12. In one example, the predetermined or resonant frequency is in the range of about 100 KHz to 10 GHz. In other examples, the predetermined frequency is in the range of about 1 MHz to 100 MHz, although other predetermined frequency will occur to those skilled in the art. System 10 further includes photo-conductor medium 16 which changes its electrical conductivity in response to incident radiation or light 18 to vary the resonant frequency of photo-controlled acoustic wave plate 12. Frequency detection device 15, which typically include frequency detector 19 and frequency analyzer 21, determines the change in the resonant frequency caused by light-induced change in the conductivity of photo-conductor medium 16.

As discussed above, directing light 18 on photo-conductor medium 16 of photo-controlled acoustic wave device 12 changes the electrical conductivity of photo-conductor medium 16. In one example, the change in electrical conductivity of photo-conductor medium 16 is in a range of about 10 to 10⁻⁶/Ωm. The light-induced change in electrical conductivity of medium 16 results in a sharp decrease, or shift, in the resonant frequency of photo-controlled acoustic wave device 12.

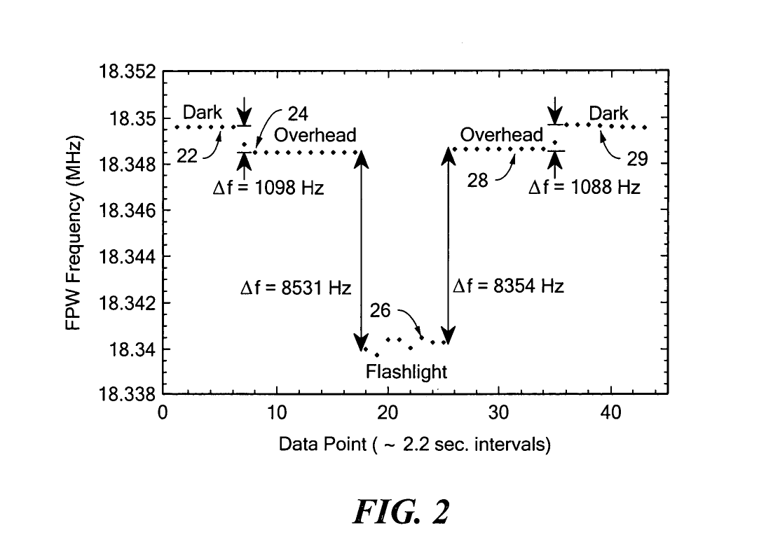

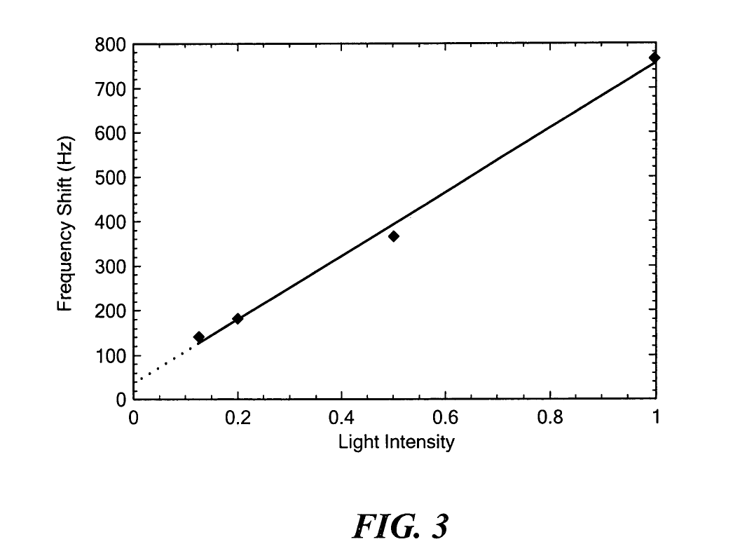

For example, FIG. 2 shows examples of various intensities of light exposure to the photo-conductor medium of this invention and the corresponding resonant frequency shift. No light exposure to the photo-conductor medium is indicated at 22. Exposure to moderate light intensity, e.g., with a fluorescent light, indicated at 24, resulted in a resonant frequency decrease, or shift, of about 1,098 Hz. Increasing the light intensity (e.g., with a device such as a hand-held flashlight), indicated at 26, produced a significant decrease or shift in the resonant frequency of the photo-controlled acoustic wave device. In this example, the resonant frequency shift was about 8,351 Hz. Reducing the intensity of light (e.g., turning the flashlight off), as indicated at 28, resulted in an increase in the resonant frequency, with a resulting resonant frequency shift of about of 8,254 Hz. Further reducing the light intensity (e.g., turning the lights off), as indicated at 29, resulted in a resonant frequency shift of 1,088 Hz. FIG. 3 depicts the linear relationship (over a decade range) between increased light intensity and absolute value of increased resonant-frequency shift of the photo-controlled sensor system of this invention.

The truly innovative photo-controlled luminescence sensor system of this invention measures a light-induced shift in resonant frequency caused by the increase in conductivity of the photo-conductor medium. The frequency-detection device then provides a rapid, e.g., within seconds for the NVR mass sensor used, measurement of the resonant frequency shift, which, as discussed below, can be used to detect the presence and/or concentration of luminescing samples. There is also no need to wait the several minutes to achieve a predetermined sample temperature (e.g., after the sample has been evaporated) prior to the measurement of a mass induced resonant frequency shift.

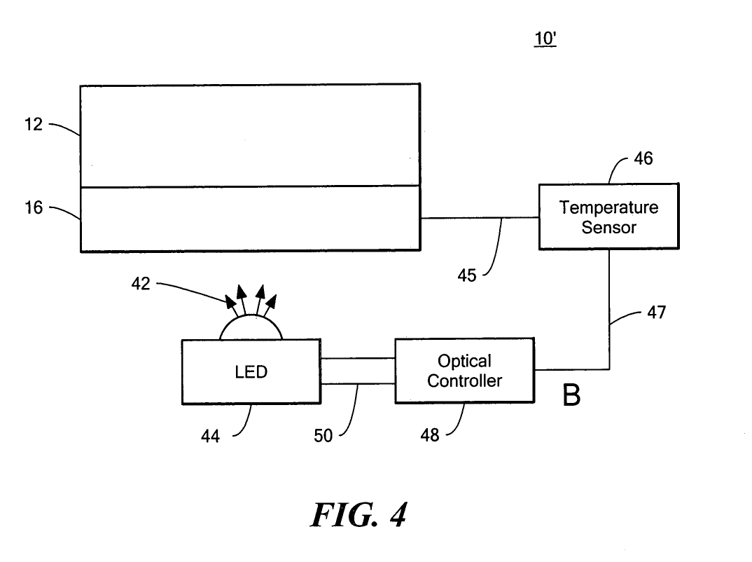

Moreover, because light may be used to induce the resonant frequency shift, system 10 can compensate for temperature variations which result from thermally induced changes to photo-controlled acoustic wave device (discussed in further detail below), less noise and error are produced. For example, controlled exposure of a light 42, FIG. 4 on the photo-conductor medium 16 of photo-controlled luminescence sensor system 10′ of this invention compensates for system induced resonant frequency shifts which may result from temperature changes in photo-controlled acoustic wave device 12 and photo-conductor medium 16 due to evaporating fluid samples (e.g., when photo-controlled acoustic wave device 12 is configured as a flexure plate wave device and includes a well 72, as described in detail below), and/or other system activities. Applying light increases the conductivity of the photo-conductor medium 16 and decreases the resonant frequency of photo-controlled acoustic wave device 12. Applying and modulating a small amount of controlled light 42 with light emitting diode (LED) 44, or similar devices known to those skilled in the art, thermally induced resonant frequency shifts of system 10′ are efficiently compensated. For example, temperature sensor 46 may be used to measure the temperature of photo-conductor medium 16 and photo-controlled acoustic device 12 on line 45. Temperature sensor 46 then sends a signal on line 47 to optical controller 48, e.g., an integrated laser diode with input control circuit, such as model number LPM785-03E, LD module, Elliptical Beam device (Newport Corporation, Irvine, Calif.), or similar device known to those skilled in the art which modulates control signals on line 50 to control the amount of light 42 emitted from LED 44. When the temperature of photo-controlled acoustic wave device 12 and photo-conductor medium 16 are elevated, optical controller 48 responds to the measured temperature by temperature sensors 46 and enables LED 44 to emit less light 42. As light level 42 emitted from LED 44 is reduced, less light is absorbed by photo-conductor medium 16 which causes the resonant frequency of photo-conductor medium 16 and photo-controlled acoustic wave device 12 to increase. The resonant frequency increase compensates for the thermally induced decrease in the resonant frequency which lowers the error associated with the temperature changes of photo-conductor medium 16 and photo-controlled acoustic wave device 12. Increasing the speed of the feedback loop between photo-conductor medium 16, temperature sensor 46, optical controller 48 and LED 42 allows for more rapid temperature compensation. The result is the ability to efficiently and rapidly compensate for thermally induced resonant frequency shifts by utilizing a small amount of controlled light, instead of relying on adjusting the temperature with complex electronics, and the like, as found in conventional sensor systems. Moreover, system 10′ of this invention can perform various measurements of samples while they are still in the liquid state, e.g., before evaporation of a liquid in well 72 is complete, in contrast to conventional systems which require total evaporation of liquid samples and then waiting for the system to cool to a predetermined temperature before the evaporated sample can be measured.

Photo-conductor medium 16, FIGS. 1 and 4 of this invention may be composed of a semiconductor or non-semiconductor medium. The non-semiconductor medium may be made of indium-tin-oxide (ITO), organic dyes, metallic salts or lead sulfide (PbS) or similar materials. The semiconductor medium may be made of silicon or similar materials known to those skilled in the art. Photo-conductor medium 16 may also have a crystalline or non-crystalline structure. Other equivalent materials and structures for non-semiconductor and semiconductor medium for photo-conductor medium 16 will occur to those skilled in the art.

In a preferred embodiment, photo-conductor medium 16 is un-doped and ideally has a dark-conductivity, (e.g., no light), of less than about 0.01/Ω-cm, a dark-resistivity of greater than about 100 Ω-cm, and a long photocarrier lifetime which is typically tens of microseconds (e.g., 30 μs). In other designs, semiconductor medium 16 may be composed of silicon and is lightly doped at a concentration of less than about 10¹⁵/cm³ with material such as boron, or similar elements known to those skilled in the art. In other embodiments, the semiconductor medium is doped at a concentration range of about 10¹³/cm³ to 10¹⁶/cm³.

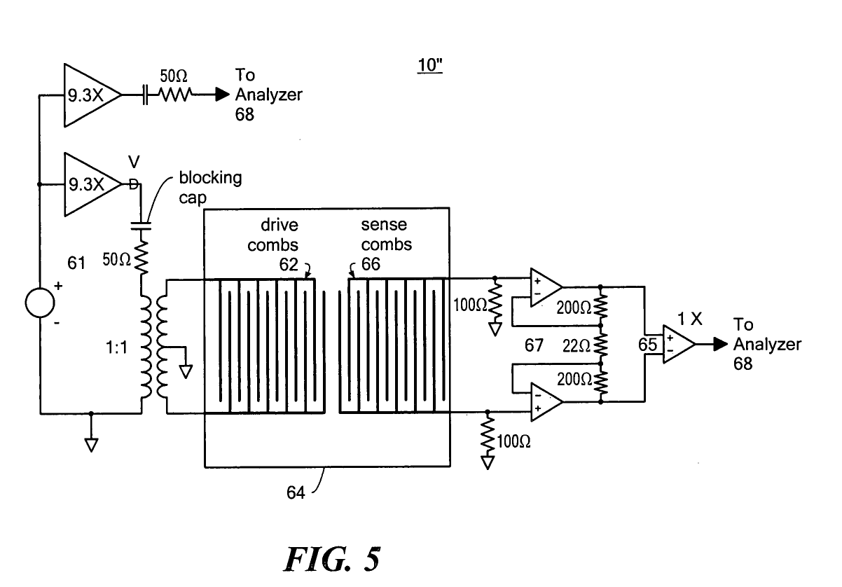

Photo-controlled luminescence sensor system 10″, FIG. 5, of this invention may include piezoelectric layer 64, and first set of transducers 62 (e.g., drive combs) disposed on piezoelectric layer 64 and a second set of transducers 66 (e.g., sense combs) disposed on piezoelectric layer 64 which are spaced from the first set of transducers 62. Further details of the electronic components and structure of transducers 62 and 66 of system 10″ as shown above are disclosed in co-pending application entitled “Flexural Plate Wave Sensor”, Ser. No. 10/675,398 filed Sep. 30, 2003.

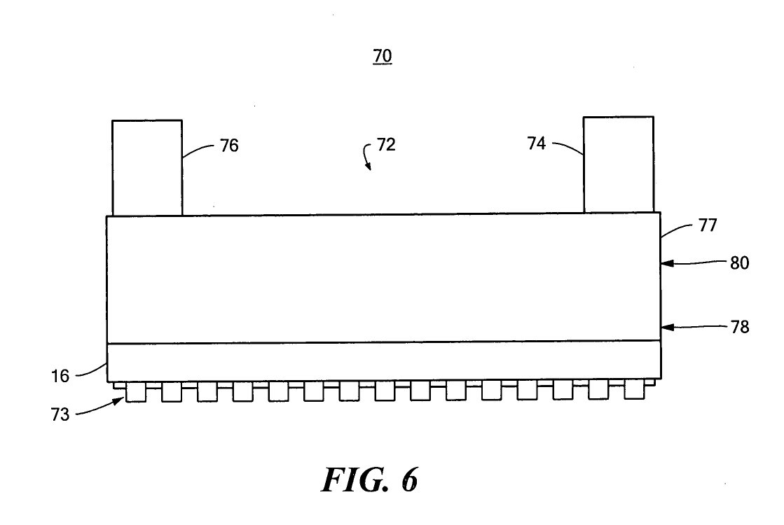

As discussed above, photo-controlled luminescence sensor systems 10 and 10′, FIGS. 1 and 4 of this invention include photo-controlled acoustic wave device 12 which, in one example, may be a flexural plate wave device, such as flexural plate wave device 70, FIG. 6. In this example, flexural plate wave device 70 includes a well 72, typically etched from single crystal silicon to form walls 74 and 76. Well 72 may be used to hold a liquid sample which may or may not be evaporated. Aluminum nitride layer (AlN) 73 may be used as the piezoelectric layer. Silicon layer 78, e.g., epiaxial silicon, may be formed by various techniques known to those skilled in the art, such as epiaxial growth. Silicon layer 78 may be employed to provide structural integrity to flexural plate device 70 and in some designs is utilized to form photo-conductive layer 16. Although, in this example, silicon is used to form layer 78 and photo-conductive layer 16, this is not a necessary limitation of this invention, as any suitable material known to those skilled in the art may be used to form layer 16. Silicon dioxide layer 80, e.g., SiO₂, may be employed as a protective layer over photo-conductive layer 16 and/or silicon layer 78 to provide desirable surface properties, e.g., low surface-recombination velocity to improve effective lifetime of photo-generated carriers.

In other designs, photo-controlled acoustic wave plate 12, FIGS. 1 and 4 may be a surface acoustic wave (SAW) or any other acoustic wave device known to those skilled in the art. SAW devices have essentially the same components as the flexural plate wave device 70, however, the relative dimensions of the components, e.g., finger spacing of the drive/sense combs, as shown in FIG. 5 above, to wave plate thickness ratio are varied to allow different dominant oscillation modes which are capable of being optimized for specific applications.

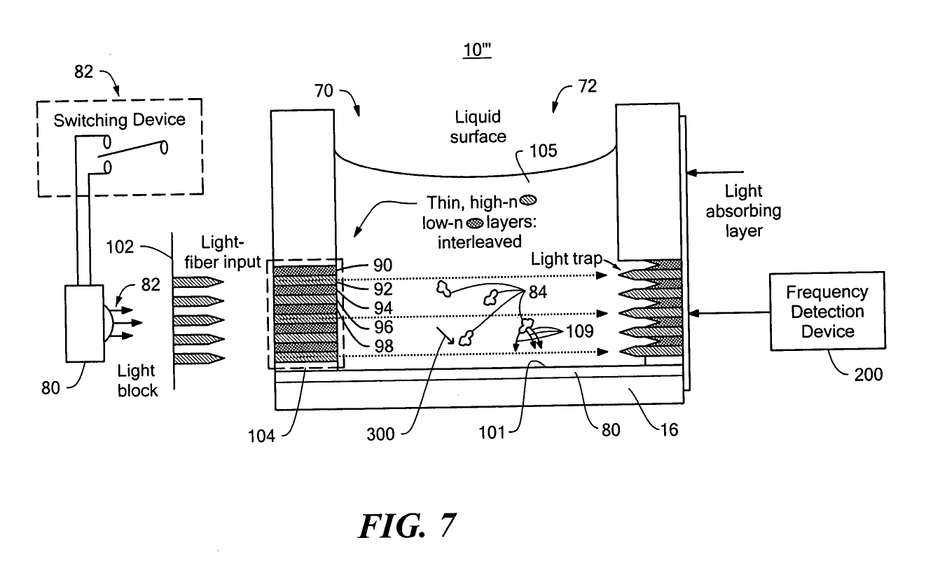

Photo-controlled luminescence sensor system 10′″, FIG. 7 of this invention includes light source 80 for emitting light 82 to excite luminescing samples 84 in well 72 of flexural plate device 70 (or similarly a SAW device) and increase the strength of the luminescence from luminescing samples 84. In one design, light from source 80 is directed parallel to layers 92, 94, 96 and 98 of optical entrance 90 (discussed in further detail below). In other designs, system 10′″ may include light confinement device 102, which in conjunction with optical entrance 90, further confines and/or directs light 82 to specific paths parallel to surface 101 of photo-conductor medium 16. In one example, light confinement device 102 may be flexible and circular to transport only low divergence angle light 82 from source 80 to optical entrance 104. Construction of optical entrance 104 is compatible with fabrication of an acoustic-wave device and permits optical transmission of light 82 into the well 72 without significantly increasing the divergence angle of excitation light 82. Optical entrance 104 typically includes a plurality of alternating interleaved high and low index of refraction layers, e.g., layers 90, 94, and 98 have low indexes of refraction while layers 92 and 96 have high indexes of refraction. Confining light parallel to layers 90-98 prevents direct impingement of excitation light 82 onto the photo-conductive layer 16. Thus, only luminescence, or scattered excitation light 109 emitted from luminescing samples 84 will cause a change in the resonant frequency of photo-conductor layer 16. Confining light to specific paths allows analysis of the sample at different levels and at different concentrations as the sample evaporates. Light trap 88 suppresses scattered exciting light 82.

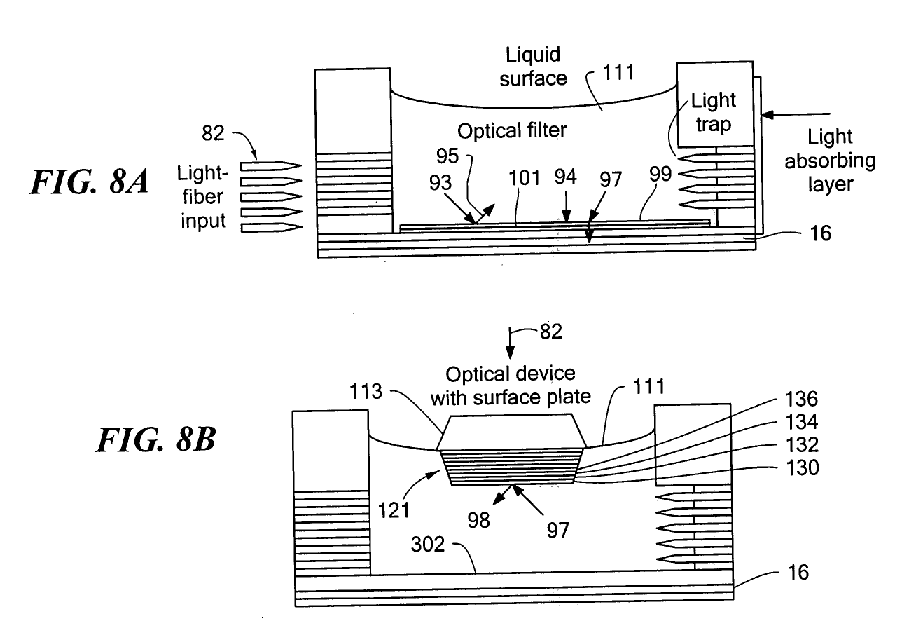

In other designs of this invention, optical filter 94, FIG. 8A may be used to isolate excitation light 82 from the luminescent light impinging on photoconductive layer 16. Optical filter 94 typically includes layer 101, typically made of selective absorption materials or interference layers, which is wavelength selective and blocks, e.g., absorbs and/or reflects a substantial portion, e.g., greater than 99%, of excitation light 82 from the photoconductive layer 16, while transmitting a significant amount, e.g., 80 to 95% of the wavelengths of the luminescent light 97 impinging onto layer 16 from solution 111. In one example, filter 94 may be a model 10LWF-700 available from Newport Corporation, Irvine, Calif. Ideally, optical filter 94 allows both scattered excitation light 93 and luminescence light 97 to be incident on optical filter 94 at all angles. Preferably, a high ratio exists between the transmitted luminescence light 97 and excitation light 82. Optical filter 94 may be optimized to provide a high ratio for luminescence light 97 to excitation light 82, e.g., at an oblique incidence angle, such as 5°. Such a design is useful when the sample solution 111 is turbid or contains constituents that can scatter or reemit wavelengths other than those of the luminescent samples. When optical filter 94 has a lower refractive index than sample solution 111, excitation light 82 may be obliquely incident on surface 99 of the layer 101 and none of scattered excitation light 93 will enter the photo-conductive layer 76, as shown by arrow 95, because of total internal reflection from surface 99 of low refractive index optical layer 101 of filter 94. Ideally, layer 101 is be very smooth to prevent scattering of the excitation light 82 into the photo-conductor layer 16 and is thick enough to prevent evanescent waves from penetrating through layer 101.

In other designs, surface plate 113, FIG. 8B reduces surface curvature from surface-tension effects of sample 111 that may increase scattered excitation light. Lower surface 121 of plate 113 may be coated with various single or multiple layers, e.g., layers 130, 132, 134 and 136, typically made of alternating layers of high and low refractive index materials transparent in the region of interest. Layers 130-136 are typically selectively reflective so that luminescent light that would normally escape detection could be reflected back, as indicated by arrows 97 and 98, to photo-conductive layer 16, while scattered excitation light could be absorbed in the layers 130-136.

Photo-controlled luminescence sensor system 10′″, FIG. 7 of the invention includes switching device 82 to turn light source 80 on and off. Turning light source 80 on causes light source 80 to emit excitation light 82. In one example, luminescing samples 84 are in solution 111. Light source 80 is turned off and frequency detection device 200 measures the resonant frequency of the flexural plate 70. Light source 80 is then turned on and frequency detection device 200 measures the resulting resonant frequency shift in flexural plate wave device 70 due to the emitted light from luminescing samples 84 in solution 111 which increase the conductivity of photo-conductor medium 16. The measured resonant frequency shift indicates the molar concentration of luminescing samples 84 in solution 111. The sensitivity of system 10′″ may be as low as 10 nM.

In one example, luminescing sample 84 of sample solution 111 may be a fluorophore, such as tryptophane, rhodamine, and other commercially available fluorophores known to those skilled in the art. The fluorophore, e.g., luminescing sample 84 which has been excited by light 82 and emits luminescence or light 109 which is absorbed by photo-conductor medium 16, increases the electrical conductivity of photo-conductor medium 16 and varies the resonant frequency of flexural plate wave device 64. Luminescing samples 84 of sample solution 111 are chosen to emit light at a wavelength which is readily absorbed by photo-conductor medium 16. Conversely, photo-conductor medium 16 may be selected to be specifically responsive to the wavelength of emitted light 109. The use of filters or frequency selective photo-conductors as described above may be used to enhance the ratio of emitted-to-excitation-light.

The photo-controlled luminescence sensor system of this invention as described above quickly measures both mass and luminescence of a particular luminescing sample. The need for separate luminescence and mass detection systems is eliminated, as is the need to wait several minutes to determine the molar concentration of luminescing samples. The mass of luminescing samples in sample solution can be quickly calculated by multiplying the measured molar concentration by the luminescent species molecular weight and the known volume to be dried. The calculated mass can be confirmed by direct measurement upon drying the sample, if non-luminescent material is absent or if its percentage is known. Conversely, the presence or percentage of non-luminescent material can be determined.

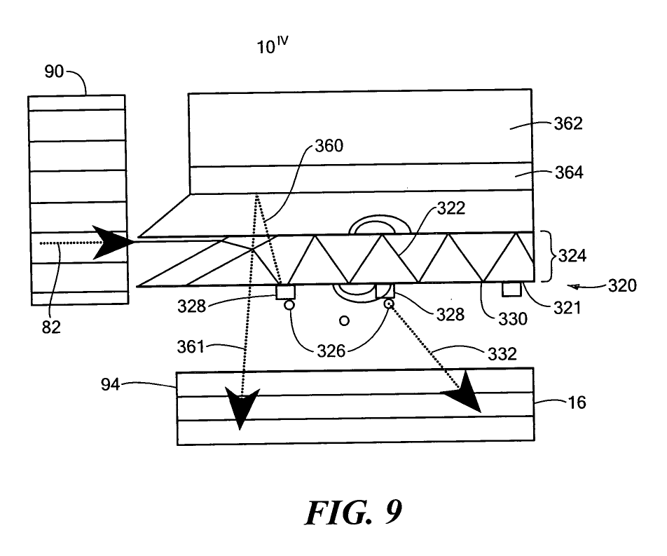

System 10^{IV}, FIG. 9, where like parts have been given like numbers, includes light-control device 320 consisting of a low-refractive index anti-reflective coating 321 plus a high-refractive index layer 324 which bends incident light 82 which is then confined by total internal reflection, as indicated by light path 322 within a high refractive-index layer 324, e.g., a light pipe. In one design of this invention, luminescing samples, such as antibodies 328, may be attached to light pipe 324. When antigens 326 bind with antibodies 328, antigens 326 become optically coupled to antibodies 328. Light 82 from within light pipe 324 causes antigens 326 coupled to antibodies 328 to emit luminescence 332 at a desired wavelength which is readily absorbed by photo conductive layer 16 and increases the conductivity of photo-conductor medium 16, while unwanted light from light 82 is confined to light pipe 324. In this design, photo mechanical luminescing sensor system 10^{IV} measures only the resonant frequency shift caused by luminescence 332 emitted from the antigen 326-antibody 328 “fluorophore” while unwanted excitation light 82 does not affect the resonant frequency shift because it is confined by total internal reflection within light pipe 324. Photo-controlled luminescence sensor system 10^{IV} can detect antigens 326 at a sensitivity as low as 10¹⁰ to 10¹¹ antigens/cm², or in solution (e.g., 1 to 10 μL), at concentrations as low as 15 ng/L.

While incident light 80 is confined within the light pipe 324, emitted or scattered light is not. For example, light 360 emitted from antigen 326-antibody 328 may be directed toward surface plate 362, as indicated by arrow 361. Reflective layer 364 reflects emitted light 360 back toward photo-conductive layer 16 which increases the total signal relative to background noise.

Although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments.

Other embodiments will occur to those skilled in the art and are within the following claims.

In addition, any amendment presented during the prosecution of the patent application for this patent is not a disclaimer of any claim element presented in the application as filed: those skilled in the art cannot reasonably be expected to draft a claim that would literally encompass all possible equivalents, many equivalents will be unforeseeable at the time of the amendment and are beyond a fair interpretation of what is to be surrendered (if anything), rationale underlying the amendment may bear no more than a tangential relation to many equivalents, and/or there are many other reasons the applicant can not be expected to describe certain insubstantial substitutes for any claim element amended.

What is claimed is:

1. A photo-controlled luminescence sensor system comprising:
a photo-controlled acoustic wave device;
an oscillator device for driving said photo-controlled acoustic wave device at a predetermined frequency, said photo-controlled acoustic wave device including a photo-conductor medium which changes its electrical conductivity in response to incident radiation to vary the predetermined frequency of said photo-controlled acoustic wave device; and
a frequency detection device for determining a change in said predetermined frequency caused by the radiation induced change in the conductivity of the photo-conductor medium.

2. The photo-controlled luminescence sensor system of claim 1 in which said photo-controlled acoustic wave device includes a flexural plate wave device.

3. The photo-controlled luminescence sensor system of claim 1 in which said photo-controlled acoustic wave device includes a surface acoustic wave device.

4. The photo-controlled luminescence sensor system of claim 1 wherein said predetermined frequency is the resonant frequency of said photo-controlled acoustic wave device.

5. The photo-controlled luminescence sensor system of claim 1 wherein said predetermined frequency is a change in frequency at a predetermined phase.

6. The photo-controlled luminescence sensor system of claim 1 in which said predetermined frequency is in the range of about 100 KHz to 10 GHz.

7. The photo-controlled luminescence sensor system of claim 1 wherein said predetermined frequency is in the range of about 10 MHz to 100 MHz.

8. The photo-controlled luminescence sensor system of claim 7 wherein said predetermined frequency is in the range of about 1 MHz to 100 MHz.

9. The photo-controlled luminescence sensor system of claim 1 wherein said photo-conductor medium is chosen from the groups consisting of: semiconductor and selected non-conductor mediums.

10. The photo-controlled luminescence sensor system of claim 9 wherein said non-conductor medium is chosen from the group consisting of: indium-tin-oxide, organic dyes, metal salts, and lead sulfide.

11. The photo-controlled luminescence sensor system of claim 9 wherein said semiconductor medium is chosen from the group consisting of: silicon, germanium, gallium arsenide, and indium arsenide.

12. The photo-controlled luminescence sensor system of claim 9 wherein said photo-conductor medium is crystalline.

13. The photo-controlled luminescence sensor system of claim 9 wherein said photo-conductor is non-crystalline.

14. The photo-controlled luminescence sensor system of claim 9 wherein said semiconductor medium is undoped.

15. The photo-controlled luminescence sensor system of claim 9 wherein said semiconductor medium is lightly doped with a doping element to change the dark conductivity of said photo conductor medium while maintaining the high photo-conductivity of said photo-conductor medium.

16. The photo-controlled luminescence sensor system of claim 15 wherein the doping element for a silicon semiconductor is chosen from the group consisting of: boron, aluminum, arsenic, and phosphorus.

17. The photo-controlled luminescence sensor system of claim 15 wherein said semiconductor medium is doped at a concentration of approximately 10¹⁵ cm⁻³.

18. The photo-controlled luminescence sensor system of claim 15 wherein said doped medium is doped at a concentration of less than 10¹⁵cm⁻³.

19. The photo-controlled luminescence sensor system of claim 15 wherein said semiconductor medium is doped at a concentration range of approximately 10¹³ cm⁻³ to 10¹⁵ cm⁻³.

20. The photo-controlled luminescence sensor system of claim 1 in which said change in electrical conductivity is in the range of about 10 to 10⁻⁶/Ωm.

21. The photo-controlled luminescence sensor system of claim 1 wherein said photo-controlled acoustic wave device includes a piezoelectric layer.

22. The photo-controlled luminescence sensor system of claim 21 further including a first set of transducers disposed on said piezoelectric layer and a second set of transducers disposed on said piezoelectric layer, spaced from said first set of transducers.

23. The photo-controlled luminescence sensor system of claim 22 wherein said first set of transducers define a drive comb and said second set of transducers define a sense comb.

24. The photo-controlled luminescence sensor system of claim 1 further including a light source for emitting said incident radiation.

25. The photo-controlled luminescence sensor system of claim 24 further including a temperature sensor for measuring the temperature of said photo-controlled acoustic wave device and said photo-conductor medium, and an optical controller device for controlling the amount of light emitted by said light source and compensating for resonant frequency shifts that result from temperature changes in said photo-conductive medium and said photo-controlled acoustic wave device.

26. A photo-controlled luminescence sensor system comprising:
a flexural plate wave device;
an oscillator device for driving said flexural plate wave device at a predetermined frequency, said flexural plate wave device including a photo-conductor medium which changes its electrical conductivity in response to sensed luminescing samples to vary the predetermined frequency of said flexural plate wave device; and
a frequency detection device for determining a change in said predetermined frequency caused by the luminescence induced change in the conductivity of the photo-conductor medium representative of the presence and/or concentration of said luminescing samples.

27. The photo-controlled luminescence sensor system of claim 26 further including a light source that emits light for exciting said luminescing samples to increase the luminescence light emitted by said luminescing sample.

28. The photo-controlled luminescence sensor system of claim 27 wherein said light source directs said light essentially parallel to said flexural plate wave device.

29. The photo-controlled luminescence sensor system of claim 27 wherein said light source directs light at an incident angle to said flexural plate wave device for illuminating said samples in a solution disposed in a well of said flexural plate while said light does not illuminate said photo-conductive layer.

30. The photo-controlled luminescence sensor system of claim 29 further including a light filter for selectively blocking excitation light from said photo-conductor medium.

31. The photo-controlled luminescence sensor system of claim 30 wherein said light filter and said incident angle of light are selected to optimize the ratio of said luminescence light to excitation light which is collected by said photo-conductive layer.

32. The photo-controlled luminescence sensor system of claim 30 wherein a filter transmission ratio of said luminescence light to said excitation light is about 100.

33. The photo-controlled luminescence sensor system of claim 26 further including a light confinement device for confining said excitation light by total internal reflection to prevent excitation light from entering said photo-conductive medium device.

34. The photo-controlled luminescence sensor system of claim 33 in which said light confinement device includes a light pipe.

35. The photo-controlled luminescence sensor system of claim 34 wherein said light confinement device includes one or more low refractive index layers.

36. The photo-controlled luminescence sensor system of claim 35 wherein said luminescing samples are attached to low refractive-index layer.

37. The photo-controlled luminescence sensor system of claim 36 in which said luminescing samples include antibodies and antigens.

38. The photo-controlled luminescence sensor system of claim 26 in which said flexural plate wave device includes a plurality of spaced walls which define a well for receiving a fluid sample.

39. The photo-controlled luminescence sensor system of claim 27 further including a switching device for switching between mass and luminescence detection.

40. The photo-controlled luminescence sensor system of claim 39 wherein a frequency difference between said excitation light source being turned on and off provides a quantitative measure of said luminescence.

41. A photo-controlled luminescence sensor system comprising:
a photo-controlled acoustic wave device;
an oscillator device for driving said photo-controlled acoustic wave device at a predetermined frequency, said photo-controlled acoustic wave device including a photo-conductor medium which changes its electrical conductivity in response to sensed luminescing samples to vary the predetermined frequency of said flexural plate wave device;
a frequency detection device for determining a change in said predetermined frequency caused by the luminescence induced change in the conductivity of the photo-conductor medium representative of the presence of said luminescing samples and a light source for exciting said luminescing samples to increase the luminescing of said sample; and
a switching device for switching between mass and luminescence detection.

42. A photo-controlled luminescence sensor system comprising:
a light source for emitting light;
a photo-controlled acoustic wave device;
an oscillator device for driving said photo-controlled acoustic wave device at a predetermined frequency, said photo-controlled acoustic wave device including a photo-conductor medium which changes its electrical conductivity in response to said light to vary the predetermined frequency of said photo-controlled acoustic wave device;
a frequency detection device for determining a change in said predetermined frequency caused by the radiation induced change in the conductivity of the photo-conductor medium;
a temperature sensor for monitoring the temperature of said photo-controlled acoustic device and said photo-conductive layer; and
an optical controller device for controlling the amount of light emitted by said light source and compensating for resonant frequency shifts that result from temperature changes in said photo-conductive medium and said photo-controlled acoustic wave device.
